(19) United States
(12) Patent Application Publication
(10) Pub. No.: US 2018/0163070 A1
(43) Pub. Date: Jun. 14, 2018

(54) SOLUTION PROCESS FOR INSB NANOPARTICLES AND APPLICATION FOR IR DETECTORS

(71) Applicant: MERCK PATENT GMBH, DARMSTADT (DE)

(72) Inventors: Ranjan Deepak DESHMUKH, Mechanicsburg, PA (US); Rebekah HOOKER, Belmont, MA (US); Yudhisthira SAHOO, East Brunswick, NJ (US); Pawel MISKIEWICZ, Southampton (GB)

(73) Assignee: MERCK PATENT GMBH, DARMSTADT (DE)

(21) Appl. No.: 15/578,063

(22) PCT Filed: May 6, 2016
(86) PCT No.: PCT/EP2016/000746

§ 371 Date: Nov. 29, 2017

Related U.S. Application Data
(60) Provisional application No. 62/168,319, filed on May 29, 2015.

(51) Int. Cl. C09D 11/52; C09D 11/037; C09D 11/322; B22F 9/20; B22F 1/00; H01L 31/0384; H01L 31/0304; H01L 31/18

(52) U.S. Cl. CPC C09D 11/52; C09D 11/037; C09D 11/322; B22F 9/20; B22F 2302/45; H01L 31/03845; H01L 31/0304; H01L 31/184; B22F 1/0018

(57) ABSTRACT

This invention relates to a process for synthesizing InSb nanoparticles, a method to stabilize them, and a method to provide a photodetector to detect infrared light.

This invention relates to a process for synthesizing InSb nanoparticles, a method to stabilize them, and a method to provide a photodetector to detect infrared light.

### PRIOR ART

Infrared radiation consists of electromagnetic waves with wavelength longer than that of visible light. Infrared radiation lies in the wavelength region ranging from 0.75 μm (1.65 eV) to 1000 μm (1200 eV). Infrared radiation can be further classified as a) near IR (NIR) from 0.75 to 1.4 μm, b) short wavelength IR (SWIR) from 1.4 to 3 μm, c) middle wavelength IR (MWIR) from 3 to 8 μm, d) long wavelength IR (LWIR) from 8 to 15 μm, and e) far IR 15 to 1000 μm (Byrnes, James (2009). Unexploded Ordnance Detection and Mitigation. Springer. pp. 21-22. ISBN 978-1-4020-9252-7). Interest has centered mainly on the wavelengths of the two atmospheric windows of 3-5 μm and 8-12 μm as the atmospheric transmission is the highest in these bands and the emissivity maximum of the objects at T=300K is at the wavelength ˜10 μm.

Various infrared detectors based on materials such as PbS, PbSe, HgSbTe, InSb, InAsSb, PbSnTe, InGaAs as well as detectors based on dopants such as Cu, Zn, Au in Ge etc. have been prepared (A. Rogalski et al., Progress in Quantum Electronics 27 (2003) 59-210). Numerous applications of Infrared detection include night vision, thermal imaging, human body detection, remote sensing, radiation thermometers, flame detectors, moisture/gas analyzers, fiber-optic communication etc.

Several commercial detectors are based on undesirable toxic elements such as lead, mercury or arsenic. The preparation of these semiconductors requires expensive single crystal growth techniques or vapor deposition or epitaxial methods followed by intensive post processing steps. Further lattice-matched compound semiconductor epitaxy has problems associated with convenient monolithic integration with silicon based integrated circuits.

Solution processed semiconductors can overcome these challenges easily. Solution processing further offers low cost, large area deposition of semiconductors, and compatability with rigid as well as flexible substrates. Synthesis of toxic nanoparticles of lead chalcogenides such as PbS and PbSe has been heavily reported in literature. Sargent et al. reported PbS based solution-processed infrared photodetectors that are superior in their normalized detectivity (i.e the figure of merit for detector sensitivity) to the best epitaxially grown devices operating at room temperature (Nature, 2006, 442, 180-183).

In contrast, only a few research articles have reported on solution processing of InSb (indium antimonide) nanoparticles, and the state of art is still in its infancy. InSb has advantages of being a direct and narrow band gap of 0.18 eV (300 K) with high mobilities up to 78000 cm²/V·s. InSb is also non toxic as compared to mercury and lead based semiconductors. Yarema et al. reported synthesis of InSb quantum dots using indium tris[bis(trimethylsilyl)-amide] In[N(SiMe₃)₂]₃, and tris(dimethylamido) antimony, Sb[NMe₂]₃ in presence of trioctylamine and trioctylphosphine (Chem. Mater. 2013, 25, 1788-1792). The indium precursor In[N(SiMe₃)₂]₃ is not commercially available and is prepared using a separate synthesis step thereby increasing the overall complexity and cost of synthesis. The antimony precursor Sb[NMe₂]₃ is commercially available however is also quite expensive and less useful for a large commercial application. Liu et al. also reported synthesis of InSb quantum dots by reacting InCl₃ and Sb[N(Si(Me)₃)₂]₃ in oleylamine in the presence of lithium triethylborohydride (LiEt₃BH), also known as Super-Hydride®. In this reaction the antimony precursor Sb[N(Si(Me)3)2]3 is not commerically available and has to be prepared using an additional synthesis step thereby increasing the overall complexity, reduced yield and higher cost of synthesis (J. Am. Chem. Soc. 2012, 134, 20258-20261). In another report, InSb nanowires were electrodeposited in the pores of anodic aluminium oxide, AAO membranes (Nanoscale Research Letters 2013, 8:69). Previously reported InSb nanoparticles in presence of strongly complexing amines like ethylenediamine, diethylene triamine or tetraethylene pentamine also suffer from formation of additional metallic phases (excess In:Sb=4:1 needed for reaction chemistry). The nanoparticles are etched by hydrochloric acid to get rid of excess metal. The acid treatment can be quite detrimental as it can alter the surface chemistry of the InSb nanoparticle unintentionally, that may result in poor electronic performance in any device. (Can. J. Chem 2001, 79, 127-130, De Lezaeta, Mater. Res. Soc. Synop. Proc 2005, 848, FF3.34, 189).

### BRIEF DESCRIPTION OF THE INVENTION

A first embodiment of the current invention is a process for the production of indium antimonide nanoparticles characterized in that a source of indium, a source of antimony and a reducing agent chosen from borohydrides and aluminium hydrides are combined in a solvent.

In another aspect of the invention an InSb nanoparticle is provided which is stabilized by tetrafluoroborate, hexafluorophosphate or hexachloroantimonate anions and a method for producing such stabilized InSb nanoparticles.

A second embodiment of the invention is directed to an ink comprising InSb nanoparticles as disclosed above and below dispersed in a liquid phase comprising one or more solvents.

The invention is finally directed to improved semiconductor electronic devices comprising InSb nanoparticles and a method of manufacturing these devices. In this aspect a detector for infrared radiation comprising a layer of InSb nanoparticles is disclosed.

### DETAILED DESCRIPTION OF THE INVENTION

This method for the production of indium antimonide nanoparticles (InSb NPs) avoids the use of complex precursors for synthesis and is still able to obtain single phase InSb nanoparticles, thereby avoiding the need to use any acid for etching away impurities as reported previously. This disclosure also demonstrates a solution based production of a photodetector capable of detecting visible light and IR radiation.

Apart from IR detectors, the devices based on InSb NPs according to the invention are also useful for other applications such as magnetic field sensors using magnetoresistance or the Hall effect, ultra-fast transistors such as fast bipolar transistors, field effect transistor capable of operating at very high frequencies such as 200 GHz (reported by Intel) etc. The InSb inks reported here can also be used in applications as above.

The process according to the current invention provides a low cost approach for synthesis of InSb nanoparticles using commercial metal salts. The nanoparticles produced are of crystalline nature, for which the term nanocrystals is used. They are preferably single-crystalline.

The indium source is preferably an indium salt which can be chosen from the following, but is not limited to, indium chloride, indium iodide, indium fluoride, indium bromide, indium acetate, indium acetylacetonate, indium methoxide, indium propoxide, indium nitrate, and other indium organic complexes.

The antimony source is preferably an antimony salt, more preferably of the oxidation state antimony(+III), which can be chosen from the following, but is not limited to, antimony chloride, antimony iodide, antimony fluoride, antimony bromide, antimony acetate, antimony acetylacetonate, antimony methoxide, antimony propoxide, antimony nitrate, and other antimony organic complexes.

The solvents be can be chosen from the following, but not limited to, water, ethylene glycol, propylene glycol, diglyme, triglyme, triethylene glycol, oleylamine, hexylamine, trioctyl amine, hexadecane, octadecene, dioctyl ether, benzyl ether, tetrachloroethylene, dichlorobenzene, hexadecane, octadecane, etc or a mixture of any of the above. In a certain embodiment the solvent preferably comprises less than 10% by weight, more preferably less than 5% by weight and most preferably contains no amines.

The reducing agent can be chosen from the following, but not limited to, sodium borohydride, lithium borohydride, potassium borohydride, tetrabutylammonium borohydride, tetraethylammonium borohydride, methyl trioctylammonium borohydride, sodium triethylborohydride, potassium triethylborohydride, lithium triethylborohydride, lithium aluminium hydride, lithium tri-tert-butoxyaluminum hydride etc or a mixture of any of the above.

The ligand or surfactant for nanoparticles can be chosen from, but not limited to, oleylamine, butylamine, hexylamine, octylamine, ethylene diamine, ethylenediaminetetraacetic acid, polyethyleneimine, hexanethiol, 1,2-ethanedithiol, dodecanethiol, trioctylphosphine (TOP), tributylphosphine (TBP), trioctylphosphine oxide (TOPO), oleic acid, polyvinylpyrrolidone (PVP), cetyl trimethyl ammonium bromide, sodium citrate, hexadecyltrimethylammonium bromide, tetrafluoroborates (provided from using e.g. triethyloxonium tetrafluoroborate Et₃OBF₄, nitrosonium tetrafluoroborate (NOBF₄) and diazonium tetrafluoroborate etc.) or a mixture of any of the above.

In order to improve the performance of the electronic device novel, electronically conducting ligands of small dimension are presented for InSb NPs. Here is presented a ligand exchange technology with tetrafluoroborate (BF₄⁻), which is able to avoid damage to the NP surface. Helms and co-workers demonstrate the utility of Meerwein's salt (Et₃OBF₄) in stripping the aliphatic ligands off amine-passivated nanocrystals (J. Am. Chem. Soc., 2011, 133 (4), pp 998-1006). By using this reagent for the present InSb NPs virtually all of the native ligands can be removed and replaced by adsorbed BF₄⁻ and optionally by additional solvent molecules like DMF molecules on the surface of the particles. BF₄⁻ type ligands are most suitable to functionalize InSb nanoparticles in order to obtain a stable dispersion and improve device characteristics.

Surprisingly, a facile route for replacing the native, mostly carbon based ligands has been found. In this aspect of the present invention, a process is provided for the preparation of InSb nanoparticles stabilized by inorganic ions including tetrafluoroborate, hexafluorophosphate or hexachloroantimonate by treatment of such NPs with a liquid medium comprising the corresponding inorganic ions. The treatment process with inorganic ions is performed in a manner that the nanoparticle surface is essentially covered with these inorganic ions. The prior ligands are preferably removed in this process. The tetrafluoroborate, hexafluorophosphate or hexachloroantimonate is provided as a solution containing such anion, which can be provided by dissolving the corresponding salts, from corresponding acids and conversions of such agents. Available and useful cations include trialkyloxonium, nitrosonium, H+, ammonium, mono/di/tri/quaternary alky ammonium, alkylpyridinium (like 1-butyl-4-methylpyridinium), alkylimidazolium (like 1-ethyl-3-methylimidazolium) and metal cations. In the trialkyloxonium, alkyl means preferably, and independently an linear or branched alkyl with 1 to 15 carbon atoms, more preferably a linear alkyl with 1 to 7 carbon atoms, and most preferable methyl or ethyl. Alkyl substituents of pyridinium and imidazolium are preferably linear or branched alkyl with 1 to 7 carbon atoms. Particularly preferred reagents are trimethyloxonium or triethyloxonium. Triethyloxonium tetrafluoroborate is widely known as Meerwein's salt.

The InSb nanoparticles can be doped by addition of various p type or n type dopants during the nanoparticle synthesis. The p type dopants include but are not limited to Be, Zn, Cd, Cu, Cr etc. and the n type dopants include but are not limited to Si, Sn, Mg, Se, S, Te etc. Changing the ligand type on the InSb nanoparticle may also result in p or n type of doping. Off-stoichiometric compositions of In to Sb in the InSb nanoparticles can also result in p or n type of doping. The impurity doping level may also be controlled by adjusting the amount of dopant in any of the doping pathways described above. Thus an intrinsic, p-type and n-type InSb ink can be synthesized enabling construction of p-n junction, p-i-n junctions and other semiconductor device configurations possible thereby improving photodetection as compared to a simple photoconducting (metal-semiconductor-metal type device).

A further embodiment of the disclosure is an ink comprising dispersed InSb nanoparticles for solution processing to produce semiconductor devices like InSb photodetectors. The ink according to the invention is preferably a printable ink. Such ink is suitable for e.g. ink-jet printing or other common printing techniques (flexography, gravure printing, lithography). In another preferred embodiment the ink is suitable for spin coating or other common coating techniques other than printing.

The InSb-based ink can be deposited by spray coating, ink-jet printing, dip coating, doctor blading or Meyer rod coating, gravure printing, flexographic printing, lithographic printing, slit coating and drop casting etc on any kind of substrate. The substrate may be insulator, semiconductor or conductor. Ink can be deposited on flexible substrates such as plastic or rigid substrate such as glass, metal foil, semiconductors (e.g. silicon, germanium, gallium arsenide etc.) or even a semi-finished device depending on the order of processing steps needed to fabricate the final device of interest.

The nanoparticle ink preferably comprises one or more of additives chosen from, but not limited to, dispersing agents like surfactants or thickeners, viscosity modifiers, surface active agents, etc.

The process for particle production and the subsequent work-up of the reaction mixture can be carried out as batch reaction or in a continuous reaction manner. The continuous reaction manner comprises, for example, the reaction in a continuous stirred-tank reactor, a stirred-reactor cascade, a loop or cross-flow reactor, a flow tube or in a microreactor. The reaction mixtures are optionally worked up, as required, by centrifugation, sedimentation, filtration via solid phases, chromatography or separation between immiscible phases (for example extraction).

### BRIEF DESCRIPTION OF THE DRAWINGS

FIG. 1 shows the X-ray diffraction spectrum using a Cu Kα x-ray source of InSb nanoparticles produced according to Example 1.

FIG. 2 shows the photoresponse of the InSb photodetector of Example 6 under broadband AM1.5 light (100 mW/cm²).

FIG. 3 shows the photoresponse of the InSb photodetector of Example 6 under monochromated light of 900 nm wavelength.

The examples below shall illustrate the invention without limiting it. The skilled person will be able to recognize practical details of the invention not explicitly mentioned in the description, to generalize those details by general knowledge of the art and to apply them as solution to any special problem or task in connection with the technical matter of this invention.

### EXAMPLES

Materials:

Antimony (III) chloride (SbCl₃, >99.99%), indium (III) chloride (InCl₃, 99.999%), polyvinylpyrrolidone (PVP, average mol wt 10,000), triethylene glycol (TEG, >99.0%), lithium triethylborohydride (1 M in THF), sodium borohydride (NaBH₄, 99%), and triethyloxonium tetrafluoroborate (Et₃OBF₄, >97.0%) were purchased from Sigma-Aldrich. Antimony (III) acetate (Sb(CH₃COO)₃, 97%) was purchased from Alfa Aesar. Acetonitrile (99.8%) and isopropyl alcohol (IPA, 99.8%) were purchased from EMD Chemicals. Oleylamine (80-90%) was purchased from Acros Organics. Ethylene glycol (EG, 99.0%) was purchased from VWR. Millipore ultra-pure water was used, with resistivity >18.0 MΩ-cm. All chemicals were used as-received.

Procedure: Antimony and indium salts and LiAlHEt₃ were handled in a glovebox with <5 ppm oxygen and moisture levels. All other chemicals were added in air. All reactions were carried out using standard air-free techniques under a Schlenk line with constant stirring.

### Example 1. Nanoparticle Synthesis Using LiAlHEt₃ Reducing Agent

22.1 mg InCl₃, 28.9 mg Sb(CH₃COO)₃, and 20 ml oleylamine were heated in a round bottom flask under vacuum to 110° C. and degassed at this temperature for 15 min. At this point, the reactant mixture was cloudy and light yellow. The reactants were then heated to 265° C. under nitrogen. Next 1.2 ml of lithium triethylborohydride solution was injected drop-wise in the flask. Upon addition of lithium triethylborohydride, the mixture immediately turned opaque brownish black. After allowing the reaction to proceed at 265° C. for 16 hours, single phase InSb nanoparticles could be obtained. Next the heat was removed and the nanoparticle solution was allowed to cool to room temperature.

The resulting particles are examined by X-ray diffraction (FIG. 1). The measured spectrum is in accordance with the reference peaks.

### Example 2. Nanoparticle Synthesis Using NaBH₄ Reducing Agent

33.2 mg InCl₃, 34.2 mg SbCl₃, 0.1 g PVP, and 20 ml ethylene glycol were heated to 110° C. and held at this temperature for 15 min in a round bottom flask. The reaction mixture was initially placed under vacuum but was switched to nitrogen upon vigorous boiling around 100° C. At this point, the mixture was a colorless solution. The reactants were then heated to 150° C. under nitrogen, by which point the solution was yellowish and clear. 1 ml ultra-pure water was added to 0.0681 g NaBH₄ in a separate vial, which dissolved within a minute and resulted in slight evolution of bubbles. The NaBH₄ solution was then immediately injected drop-wise into the reaction mixture resulting in a dark black solution instantly. After allowing the reaction to proceed at 150° C. for 16 hours, single phase InSb nanoparticles could be obtained. Next the heat was removed and the nanoparticle solution was allowed to cool to room temperature.

### Example 3. Nanoparticle Synthesis Using NaBH₄ Reducing Agent

221 mg InCl₃, 228 mg SbCl₃, 0.1 g PVP, and 50 ml triethylene glycol were heated under vacuum to 110° C. and degassed at this temperature for 15 min. At this point during the reaction, the mixture was a clear yellow-orange solution. Next, the reaction mixture was heated to 165° C. under nitrogen, resulting in a dark orange clear solution. In a separate vial, 20 ml triethylene glycol was added to 0.455 g NaBH₄ and the mixture was sonicated followed by stirring for 30 min. After sonicating/stirring, the cloudy translucent white NaBH₄ suspension was injected drop-wise to the reaction mixture, which turned opaque black instantly. The temperature of the reaction mixture was then raised to 200° C. After 16 hours of reaction time, single phase InSb nanoparticles could be obtained. Next, the heat was removed and the nanoparticle solution was allowed to cool to room temperature.

### Example 4. Ligand Exchange Protocol and Ink Preparation

4.5 g Et₃OBF₄ was dissolved in 50 ml of isopropanol and 50 ml of acetonitrile to prepare a ligand stock solution with total concentration of Et₃OBF₄ of 0.25 M. The reaction mixture (from examples 1, 2 or 3) was collected and centrifuged as-is at 10,000 rpm for 5 min. The supernatant was poured off and the solids were redispersed in 10 ml of Et₃OBF₄ stock solution using sonication. Next the resulting nanoparticle dispersion was centrifuged again at 8000 rpm for 5 min. The supernatant was poured off and the solids were redispersed in 10 ml of acetonitrile. The resulting ink was stable and free of agglomerates and was used to deposit films of InSb nanoparticles.

### Example 5. InSb Film Preparation/Characterization

The ink prepared in example 4 was drop casted on a glass substrate to make a 0.1-10 μm thick InSb layer. Next the film was heated at 400° C. for 10 s in a nitrogen environment to improve the electronic properties of the film.

### Example 6

### Photodetector Device Construction/Testing:

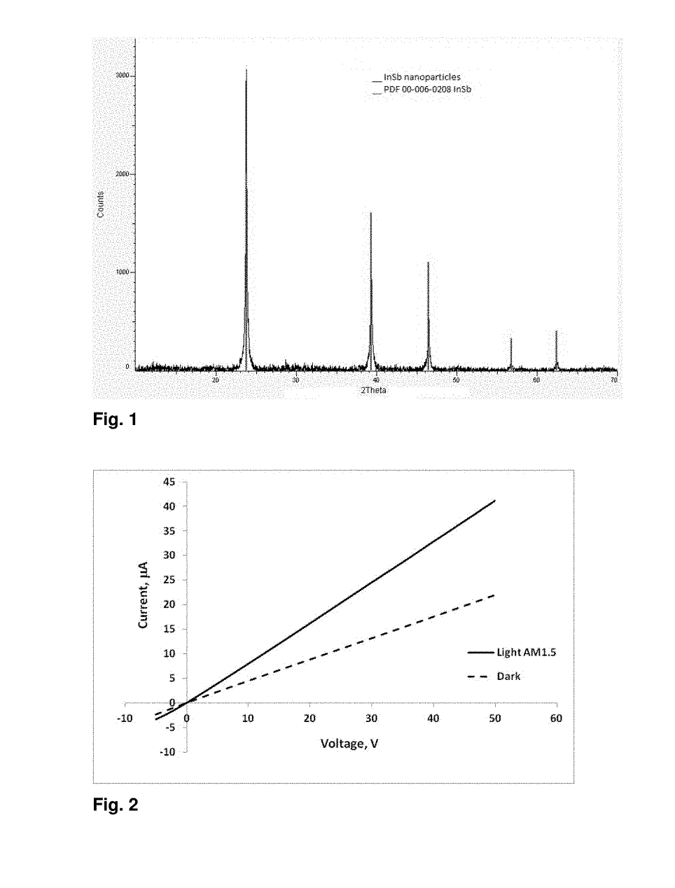

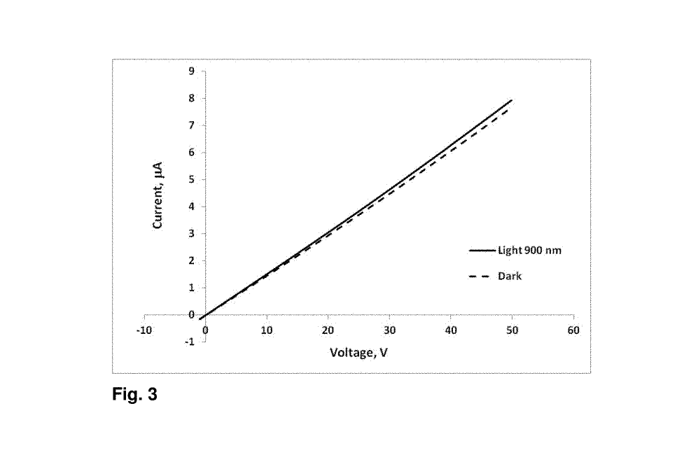

Two parallel metal electrodes were deposited on the InSb film by coating a commercial silver ink or sputtering a patterned gold layer. The electrodes were spaced 2 mm apart and were 10 mm in length. FIG. 2 shows a current vs. voltage plot of the InSb phtotodetector in dark vs light (AM 1.5, broadband light). Clearly the current value under light exposure is higher than under dark showing an appreciable photoresponse. FIG. 3 shows that the device is photoresponsive upon exposure to a monochromated infrared light source (in this case 900 nm).

Further combinations of the embodiments of the invention and variants of the invention are disclosed by the following claims.

1. Process for the production of indium antimonide nanoparticles characterized in that a source of indium, a source of antimony and a reducing agent chosen from borohydrides and aluminium hydrides are combined in a solvent.

2. Process for the production of indium antimonide nanoparticles according to claim 1, characterized in that the solvent contains less than 10% by weight amines.

3. Process for the production of indium antimonide nanoparticles according to claim 1, characterized in that the reducing agent is selected from tetrahydroborates or trialkylhydroborates.

4. Process for the production of indium antimonide nanoparticles according to claim 1, characterized in that the nanoparticles are single-phase nanocrystals.

5. Process for the production of indium antimonide nanoparticles according to claim 1, characterized in that the source of antimony is an antimony(III) salt.

6. Process for the production of indium antimonide nanoparticles according to claim 1, characterized in that the source of indium and the source of antimony are combined firstly in a solvent, and the reducing agent is added to the resulting mixture.

7. Process for the production of indium antimonide nanoparticles according to claim 1, characterized in that the solvent comprises 10% by weight or more of an amine and the reducing agent is a trialkylborohydride.

8. Process for the production of indium antimonide nanoparticles according to claim 1, characterized in that the source of indium and the source of antimony are combined and heated to 100° C. or more.

9. Process for the production of indium antimonide nanoparticles according to claim 1, characterized in that the particles are stabilized by tetrafluoroborate, hexafluorophosphate or hexachloroantimonate anions by contacting the nanoparticle surface with aforementioned ligands.

10. A semiconducting electronic device comprising a layer of indium antimonide nanoparticles.

11. A semiconducting electronic device according to claim 10, characterized in that the device is a detector for infrared radiation

12. A method of providing a semiconducting device according to claim 10, comprising the steps:
a) depositing a layer of indium nanoparticles on a substrate,
b) providing electrodes to the layer,
c) optionally heating the layer of nanoparticles.

13. Indium antimonide nanoparticle stabilized by tetrafluoroborate, hexafluorophosphate or hexachloroantimonate anions.

14. Process for the production of an indium antimonide nanoparticle stabilized by tetrafluoroborate, hexafluorophosphate or hexachloroantimonate anions according to claim 13, characterized in that such InSb nanoparticle is treated with tetrafluoroborate, hexafluorophosphate or hexachloroantimonate anions respectively.

15. Ink comprising InSb nanoparticles according to claim 12 dispersed in a liquid phase comprising one or more solvents.
